(19) United States
(12) Patent Application Publication
(10) Pub. No.: US 2008/0223598 A1
(43) Pub. Date: Sep. 18, 2008

(54) ALL ENVIRONMENT COMMUNICATIONS ENCLOSURE

(76) Inventor: Michael Burd, Herzlia (IL)

Correspondence Address: MAINNET COMMUNICATIONS, 47 HANESSIIM ST., RA'ANANA, 43583, IL

(21) Appl. No.: 12/046,485

(22) Filed: Mar. 12, 2008

Related U.S. Application Data
(60) Provisional application No. 60/894,701, filed on Mar. 14, 2007.

(51) Int. Cl. H05K 5/06; H02B 1/30; B23P 11/00

(52) U.S. Cl. 174/50.5; 174/520; 174/61; 174/50.61; 29/525.01

(57) ABSTRACT

A communications enclosure apparatus for use in a power line communications network, including a box, the box including a connection mechanism to connect the box to a standard interface of an electricity device, and the box including a water proofing system to provide the communications enclosure with all environment functionality.

### CROSS REFERENCE TO RELATED APPLICATIONS

This application claims priority from U.S. Provisional Patent Application No. 60/894,701, filed 14 Mar. 2007, entitled “ALL ENVIRONMENT COMMUNICATIONS ENCLOSURE”, which is incorporated in its entirety herein by reference.

### BACKGROUND

It is well known that electronic and communications equipment is sensitive, amongst other things, to dust, moisture, dirt and water. In particular, electronics and communications equipment as used in creating power line communications networks may be setup in moist, dusty, windy, cold, hot, rainy, and underground environments.

Furthermore, it is known that electronic and communications equipment must generally be coupled to an electric circuit, which entails a danger element when setting up, and a variety of risks associated with unreliable connections and positioning of electronic and communications equipment. Additionally electronic and communications equipment are often setup in ways that are unwieldy, in the way, and unaesthetic.

There is a great need for providing an enclosure that can protect electronic and communications equipment from the elements, and yet is easy and safe to setup and deploy.

### SUMMARY OF THE INVENTION

There is provided, in accordance with an embodiment of the present invention, a communications enclosure apparatus for use in a power line communications network, including a box, the box including a connection mechanism to connect the box to a standard interface of an electricity device, and the box including a water proofing system to provide the communications enclosure with all environment functionality.

According to some embodiments a communications enclosure apparatus for use in a power line communications network, may include a box, where the box includes a connection mechanism to connect box to a standard interface of an electricity device, and the box includes a water proofing system to provide the communications enclosure with all environment functionality.

In further embodiments the box is attachable to an electric box environment using one or more attachment mechanisms, including screws, nails, straps, strips or ties, connection mechanisms, and snap or lock on mechanisms.

In further embodiments the communications enclosure includes a connection panel for enabling an electric cable to be connected into the enclosure, wherein the connection panel hermetically seals the enclosure. In further embodiments the communications enclosure includes a cap to seal the entry of the electric cable.

In yet further embodiments a method of connecting a communications enclosure to an electricity device is provided, that includes coupling an enclosure box to an electric device outlet, where the enclosure has a shape suitable for locking onto the electric device outlet, and wherein the enclosure includes a water proofing system.

In a further embodiment, installing the communication enclosure may be placed in position, and locked in position using a locking mechanism selected from the group consisting of a connection mechanism, lock-on bracket, catching mechanism, click in components, string, rope, tape, belt, strap, strip and tie.

In an additional embodiments a power line communications system includes a plurality of communication enclosures, each communication enclosure including a communications modem, a controller, and power line networking code, each enclosure being connected to an electric device, and wherein the electric devices are connected to form a power line network; wherein the box includes a connection mechanism to connect the box to a standard interface of an electricity device, and wherein the box includes a water proofing system to provide the communications enclosure with all environment functionality.

In a further embodiment the power line communications system enclosures are deployed in locations, including electric boxes, electric meters, gas meters, water meters, electricity poles, underground electric apparatus, underwater electric apparatus, network devices and electric outlets.

### BRIEF DESCRIPTION OF THE DRAWINGS

The principles and operation of the system, apparatus, and method according to the present invention may be better understood with reference to the drawings, and the following description, it being understood that these drawings are given for illustrative purposes only and are not meant to be limiting, wherein:

FIGS. 1A-1D are graphical representations of a communications enclosure, according to some embodiments;

FIG. 2 is a schematic diagram of a communications enclosure and its components, according to some embodiments;

FIGS. 3A-3G are schematic diagrams of a connection interface, according to some embodiments;

FIG. 4 is a graphical representations of communication enclosure holders, according to some embodiments; and

FIGS. 5A-5C are graphical representations of a meter adaptor interface, according to some embodiments;

FIGS. 6A-6B are graphical representations of a connection panel according to some embodiments; and

FIGS. 7A-7G are a series of graphical drawings showing different angles and elements of the communication enclosure, according to some embodiments.

It will be appreciated that for simplicity and clarity of illustration, elements shown in the drawings have not necessarily been drawn to scale. For example, the dimensions of some of the elements may be exaggerated relative to other elements for clarity. Further, where considered appropriate, reference numerals may be repeated among the drawings to indicate corresponding or analogous elements throughout the serial views.

### DETAILED DESCRIPTION OF THE INVENTION

The following description is presented to enable one of ordinary skill in the art to make and use the invention as provided in the context of a particular application and its requirements. Various modifications to the described embodiments will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed. In other instances, well-known methods, procedures, and components have not been described in detail so as not to obscure the present invention.

In the following detailed description, numerous specific details are set forth in order to provide a thorough understanding of the present invention. However, it will be understood by those skilled in the art that the present invention may be practiced without these specific details.

The phrase “communications enclosure” as used herein may encompass any suitable hardware component that may be used to hold communications hardware, software, firmware and/or embedded elements, for example, modems, boxes, capsules, containers, panels or other structures. Communications enclosure may further include components to support communications, electrical equipment (e.g., switches, fuses, sensors etc.), computing devices, display devices etc. The phrase “all environment” as used herein may include usage of embodiments of the invention in multiple environments, for example, outdoors, underground, in wet environments, hot environments, cold environments etc.

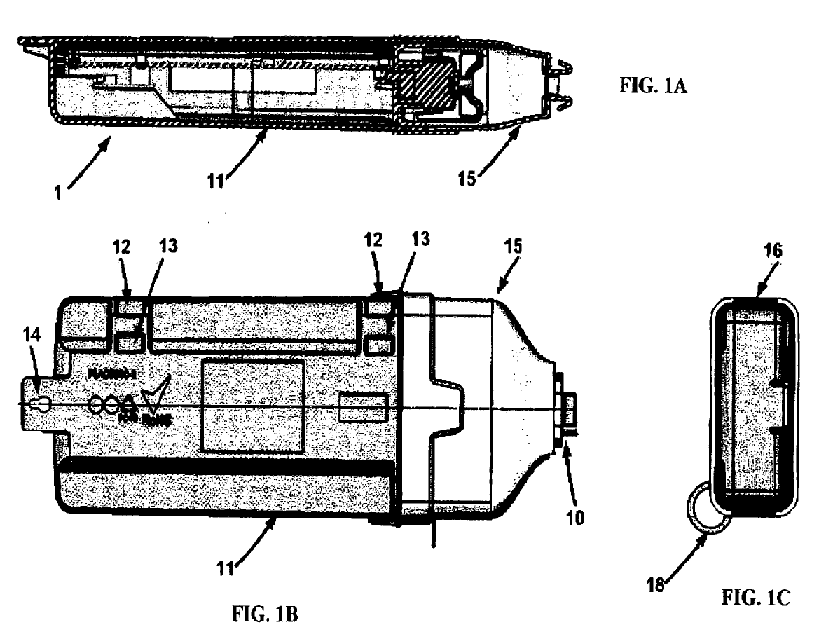

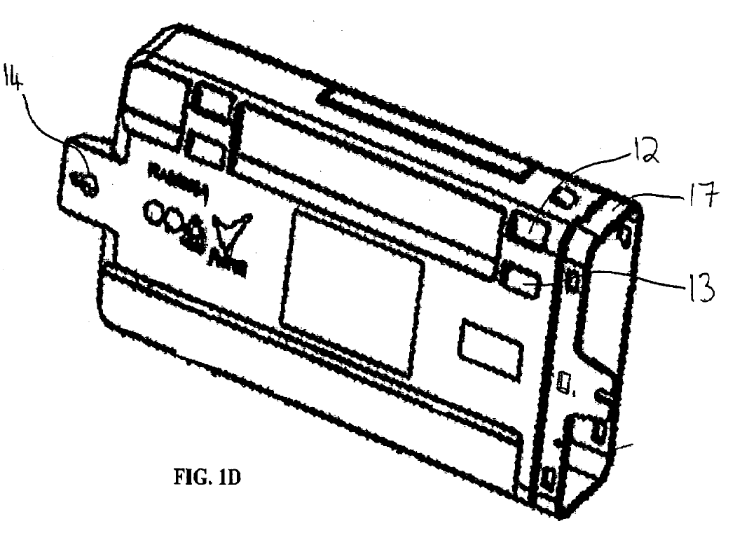

Reference is now made to FIGS. 1A-D which are graphical illustrations of a communications enclosure, according to some embodiments. Communications enclosures may include a communications modem, a controller, and power line networking code, wherein each enclosure is connected to an electric device, such that the electric devices are interconnected to form a power line network. The enclosures may be deployed in locations including electric boxes, electric meters, gas meters, water meters, electricity poles, underground electric apparatus, underwater electric apparatus, network devices and other electric outlets or devices. As can be seen in FIGS. 1A-C, the communications enclosure may have a shape and features that may enable communications enclosure to be rapidly connected with a standard electric meter, or an electric wire. For example, box 1 may be connected to a standard outlet of an electricity user, by joining connection mechanism, for example bracket 10, with the standard interface or outlet of an electricity device, for example, an electric meter, gas meter, water meter, electricity panel, or other electric equipment, allowing for rapid and effective setup or deployment of the communications enclosure with standard electric equipment. Such deployment also provides safety advantages, for example, by providing a strong connection that shields the electric wires from human contact outside the communications enclosure.

In some embodiments communications enclosure 1 may be positioned in an electric box, pole or platform, or other suitable device location, using loop holders 12 and 13. For example, a string, rope, tape, belt, strap, strip, tie or other suitable relatively thin tying device, optionally with scotch, catching hooks or other lockable mechanisms, may be threaded between loop holders 12 and 13, and around a suitable electric feature, to enable easy placing or deployment of communications enclosure 1. In one example communications enclosure 1 may be hung on a strong electric wire, such as the neutral wire. In further embodiments communications enclosure 1 may be positioned using nail or screw hole 14. In some embodiments the communications enclosure may include suitable brackets, catching mechanism, click in components or other suitable components to enable the enclosure to be clipped in or otherwise attached to an electricity box, meter, pole, wire etc., optionally without screws, nails, drilling or other attaching procedures or tools.

In some embodiments the communications enclosure may be water proof, thereby enabling setup and implementation of any wire communications including but not limited to power line communication, in dusty, moist, wet or even liquid environments, for example, outside, underground or in low lying areas such as basements. For example, the communications enclosure may be constructed from plastic with a box cover 15, connectors panel 16, and seals 18, that enable the communications enclosure to be strongly or hermetically sealed, thereby enabling waterproofing of the communications enclosure and the relevant connected electric wires. The communications enclosure may be constructed so as to withstand elements, for example, whether installed outdoors, underground, in moist or wet environments etc. Other forms, shapes, materials and/or features may be used.

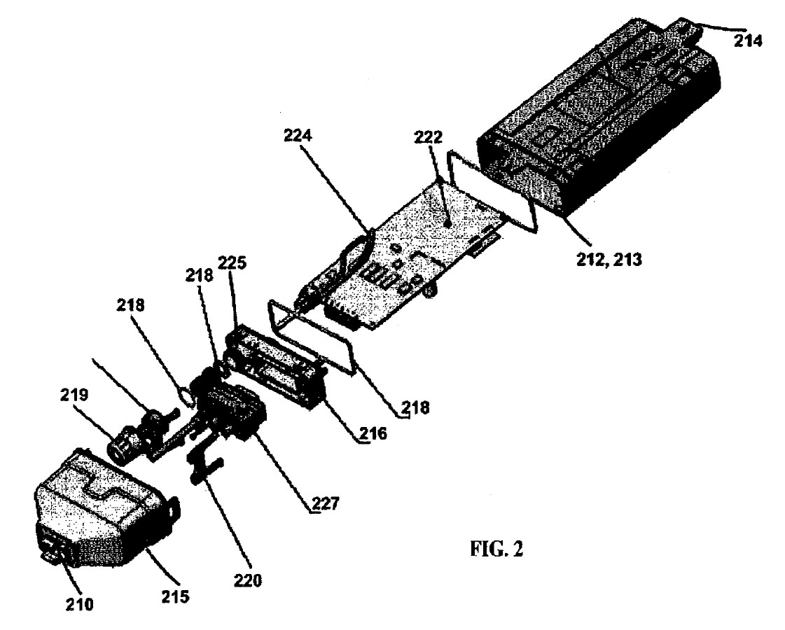

According to some embodiments, as can be seen with reference to FIG. 2, the communications enclosure may include components to enable any wire communications including but not limited to power line communication, for example, hardware, software, firmware, electronic equipment, electric circuits and other components. According to some embodiments, as can be seen with reference to FIG. 2, communications enclosure 211 may include a connection mechanism 210 for connecting the enclosure to an electric meter outlet, or an electric wire or cable. This connection mechanism may include a connector interface that may include a locking mechanism for locking onto a meter box or unit, Communications enclosure may have a variety of fixation features, for example, to enable the enclosure to be installed on standard fixation points, non standard fixation points, electricity boxes, electric meters, walls, poles, etc. For example, the enclosure may include openings 212, 213, through which a positioning strap, strip or tie may be thread, for connection to a suitable electricity cable, box, door etc. In other embodiments communications enclosure 211 may include a screw or nail hole 214 that may be used to position communications enclosure 211 using standard screws or nails.

Communications enclosure 211 may be of a suitable shape and size to include communications and/or electronics components, such as a printed circuit 222, communications cables 224, processes, chips, converters, transformers, etc. Communications enclosure 211 may be closed off with a connectors panel 216, which may seal the box, yet leave an access space for the relevant electric cables or wires. Cable hole may be sealed with a rubber plug 219, for example, when not in use. Connectors panel 216 may enable a cable connector 227 to be connected, and may be shaped accordingly to provide a sealed closure around the cable connector 227. Brackets 220 and/or other locking mechanisms may be used to join box cover 215 to connectors panel 216. Communications enclosure 211 may be sealed with a variety of rubber or plastic bands 218, providing water proofing to all suitable joining areas or connection points.

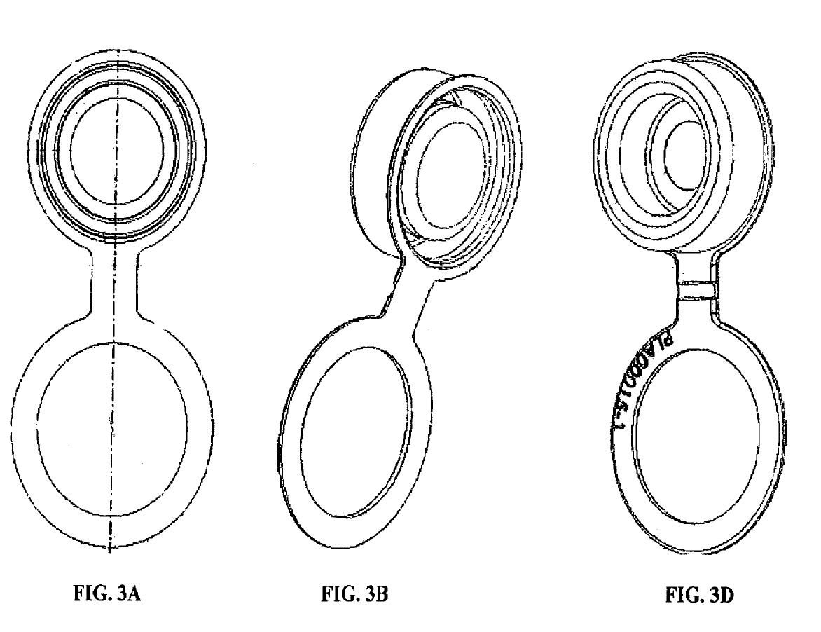

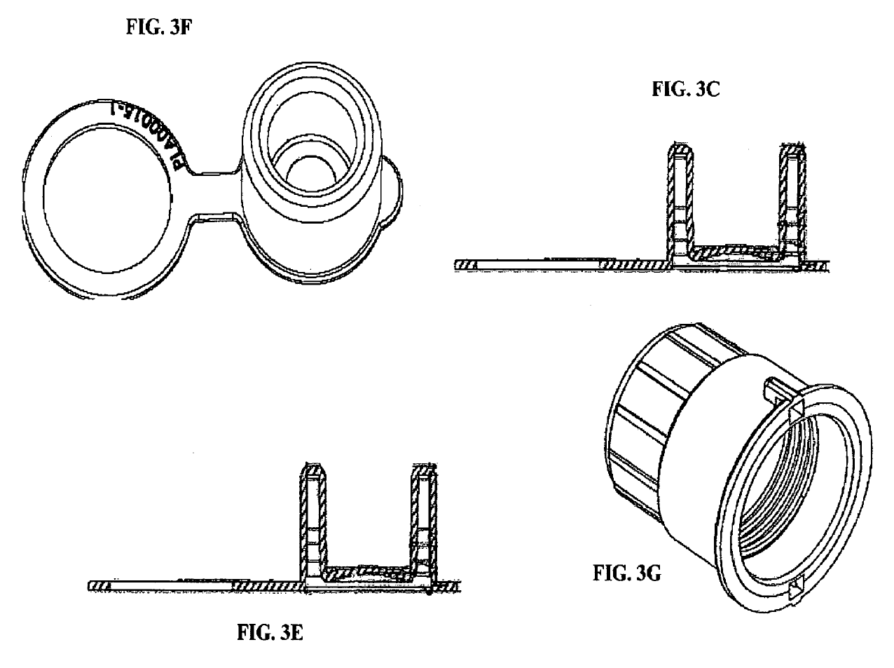

Reference is now made to FIGS. 3A-3G, which illustrate a cap or cover, for example, that may cover cable or connector inlet to provide a water proofing. The cap may include a rubber or plastic closing mechanism made from a plastic material, for example, that expands in heat and contracts in cold, such as plastic or rubber; and at least one compound made from polyethylene, rubber, plastic or an equivalent material that facilitates contraction in heat and expansion in cold. In some examples an inner and outer closing element of cap may be constructed from the above materials, thereby ensuring that closure will be attained in hot, cold or any other environments. Other forms, shapes, materials, components and/or features may be used.

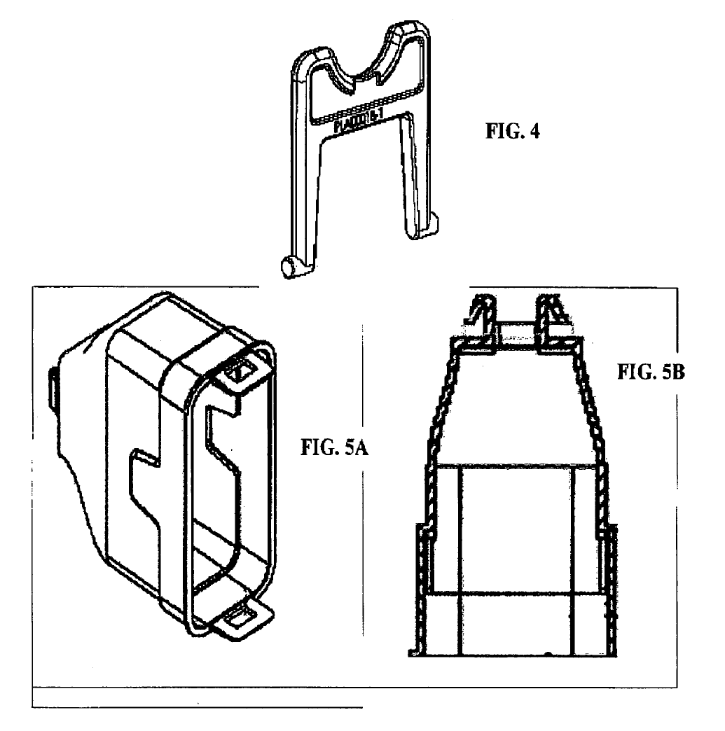

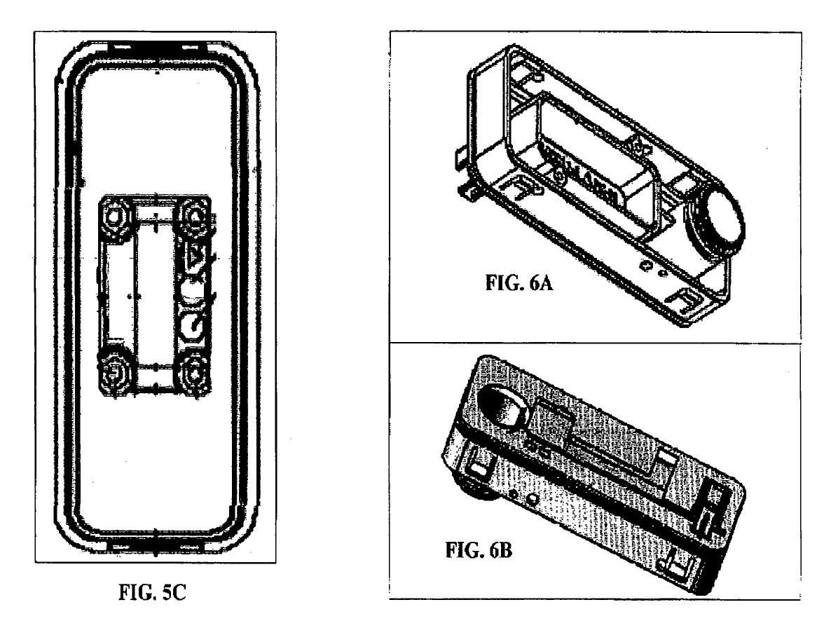

Reference is now made to FIG. 4, which shows an example of a locking bracket or holding mechanism-, which may be connected to communication enclosure to fix a connection cable or other external components to the communications enclosure. FIGS. 5A-5C also illustrate a variety of connection holders 50. FIGS. 5A-5C further illustrate examples of a cover or adapter, for example, to connect communications enclosure to external equipment, such as electric meters, gas meters, water meters, etc. Other forms, shapes, materials, components and/or features may be used.

Reference is now made to FIGS. 6A-6B, which shows examples of connector panels. Connector panels may be used, for example, to cover the connection components and provide water proofing for the components inside the communications enclosure. In some embodiments the panels may be fitted with plastic or rubber based connection components, for example, plugs and seals that may enable moisture sensitive points to be protected. For example, the electricity cable connection point and Ethernet cable connection point may be suitable insulated using connection interfaces in connection with the connector panels. Other forms, shapes, materials, components and/or features may be used.

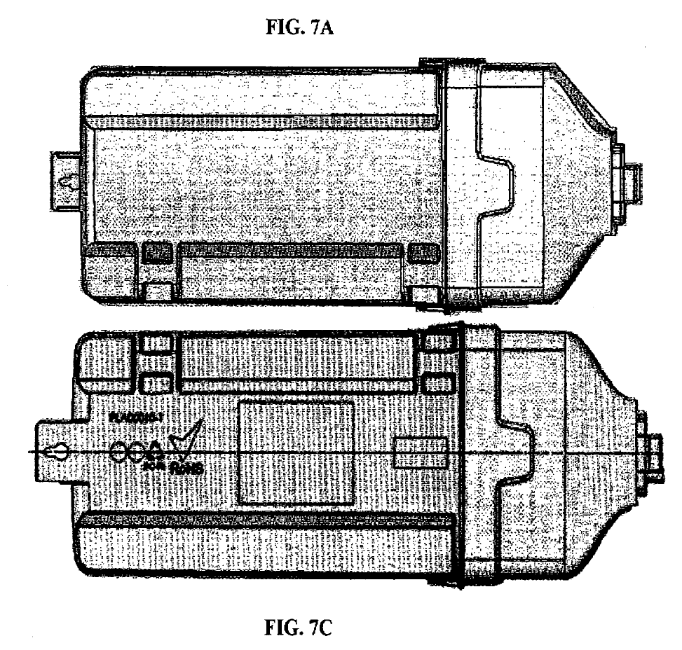

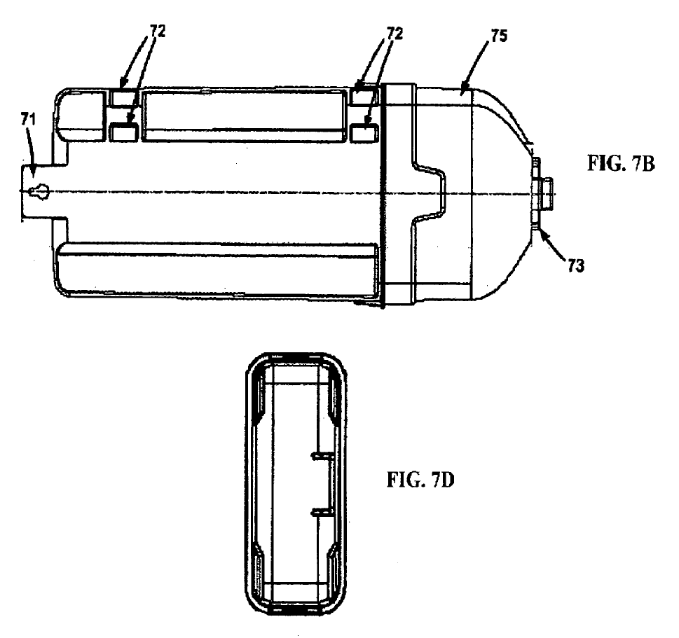

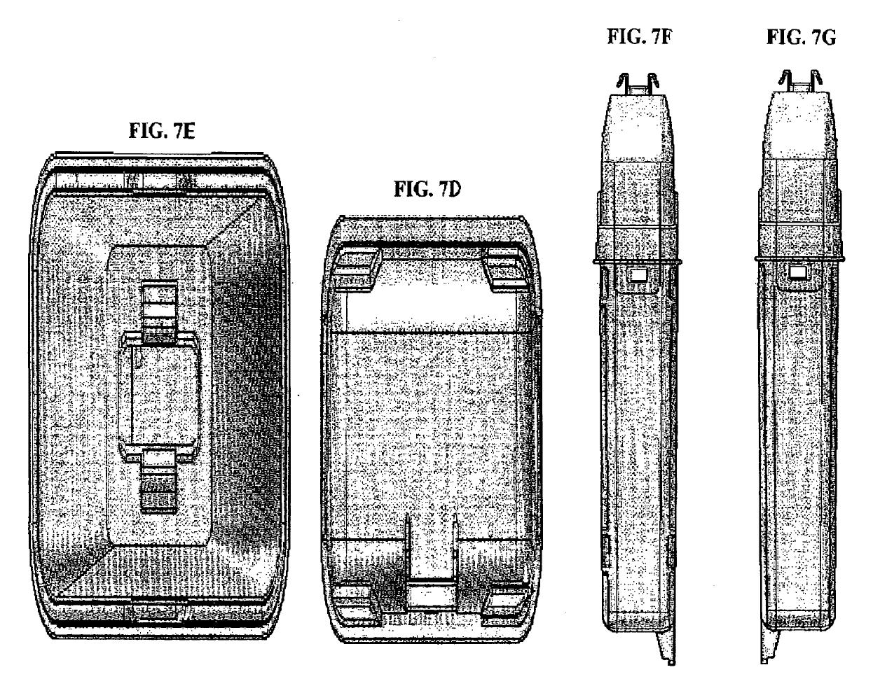

Reference is now made to FIGS. 7A-7G, which shows graphic examples of views of a communications enclosure, according to some embodiments. As can be seen in the figures, the enclosure in FIG. 7A may be shaped precisely so as to be easily placed into an available slot in an electric box, since the length, height, width and depth are suitable to the typical dimensions of electric box components, for example, electric meters. As can be seen in FIGS. 7B and 7C, the front panel (i.e. the internal side facing the electric box wall) of the enclosure may include nail or screw hole/holder 71, strap holders 72, connector mechanism 73, and box cover 75. FIG. 7D illustrates the enclosure's back panel (i.e. the external side) that faces outwards when deployed. FIG. 7E illustrates the enclosure's top side, to which the electric wire(s) from the electric box or pole etc. may connect. The connecting mechanism shown 77 includes one or more click locks to click and lock into an element being coupled, for example, a electric meter. FIGS. 7F and 7G illustrate the side panels of the enclosure. According to some embodiments, pipe or cord entry window may include a rubber membrane to prevent the entry of water, dust or other unwanted materials into the enclosure. Furthermore, enclosure may be constructed from a hardened plastic compound, to provide a light, durable and waterproof outer surface.

The foregoing description of the embodiments of the invention has been presented for the purposes of illustration and description. It is not intended to be exhaustive or to limit the invention to the precise form disclosed. It should be appreciated by persons skilled in the art that many modifications, variations, substitutions, changes, and equivalents are possible in light of the above teaching. It is, therefore, to be understood that the appended claims are intended to cover all such modifications and changes as fall within the true spirit of the invention.

What is claimed is:

1. A communications enclosure apparatus for use in a power line communications network, comprising:
a box, said box including a connection mechanism to connect box to a standard interface of an electricity device, and said box including a water proofing system to provide the communications enclosure with all environment functionality.

2. The communications enclosure of claim 1, wherein said box is attachable to an electric box environment using one or more attachment mechanisms selected from the set of screws, nails, straps, strips or ties, connection mechanisms, and snap or lock on mechanisms.

3. The communications enclosure of claim 1, comprising a connection panel for enabling an electric cable to be connected into the enclosure, wherein said connection panel hermetically seals the enclosure.

4. The communications enclosure of claim 3, comprising a cap to seal the entry of said electric cable.

5. A method of connecting a communications enclosure to an electricity device, comprising coupling an enclosure box to an electric device outlet, where said enclosure has a shape suitable for locking onto said electric device outlet, and wherein said enclosure includes a water proofing system.

6. The method of claim 5, comprising installing the communication enclosure in position, and locking the enclosure in said position using a locking mechanism selected from the group consisting of a connection mechanism, lock-on bracket, catching mechanism, click in components, string, rope, tape, belt, strap, strip and tie.

7. A power line communications system, comprising:
a plurality of communication enclosures, each said communication enclosure including a communications modem, a controller, and power line networking code, each said enclosure being connected to an electric device, said electric devices being connected to form a power line network;
wherein said box includes a connection mechanism to connect said box to a standard interface of an electricity device, and wherein said box includes a water proofing system to provide the communications enclosure with all environment functionality.

8. The power line communications system of claim 7, wherein said enclosures are deployed in locations selected from the set comprising electric boxes, electric meters, gas meters, water meters, electricity poles, underground electric apparatus, underwater electric apparatus, network devices and electric outlets.
